(19) United States
(12) Patent Application Publication
(10) Pub. No.: US 2025/0153761 A1
(43) Pub. Date: May 15, 2025

(54) ELECTRICAL CIRCUIT CONFIGURATION FOR ALTERNATING HEATING AND CAPACITIVE MEASURING OPERATION WITH FUNCTIONAL TESTING AND ASSOCIATED METHOD AND USE

(71) Applicant: Preh GmbH, Bad Neustadt a.d. Saale (DE)

(72) Inventors: Manfred SCHNEIDER, Oberthulba (DE); Friedrich WIELAND, Bad Neustadt a.d. Saale (DE)

(73) Assignee: Preh GmbH, Bad Neustadt a.d. Saale (DE)

(21) Appl. No.: 18/832,683

(22) PCT Filed: Jan. 20, 2023
(86) PCT No.: PCT/EP2023/051340

§ 371 Date: Jul. 25, 2024

(30) Foreign Application Priority Data
Jan. 27, 2022 (DE) 10 2022 101 912.8

(51) Int. Cl. B62D 1/06; B62D 1/04; G01D 5/20; G01D 5/24; H05B 3/06

(52) U.S. Cl. CPC B62D 1/06; B62D 1/046; G01D 5/20; G01D 5/2405; H05B 3/06

(57) ABSTRACT

The present disclosure relates to a circuit and a method for carrying out an alternating heating and capacitive measuring operation by means of a common heating wire, comprising the following steps: carrying out a heating operation, during which a pair of first switching elements and a pair of second switching elements are in a conducting state and the heating wire is conductively connected to one of two different heating potentials such that a heating current is applied to the heating wire; initiating a change from heating operation to measuring operation of the first switching elements and the second switching elements by way of a control circuit; carrying out the measuring operation in which a measuring capacitance of the heating wire is determined with respect to a reference potential by way of a detection circuit; and carrying out a test phase falling within the time frame of the measuring operation.

### BACKGROUND

The steering wheel and the driver's seat of a motor vehicle is usually provided with an electric heater as a comfort function in vehicles; for this purpose, the grip area, in particular the steering wheel rim of the steering wheel or the seat cushion and the back cushion of the seat have a heating wire passing through them. For safety considerations, but also to realize additional comfort functions, there is also a need to be able to carry out touch detection or at least approach detection, such as so-called hands-on detection, in which it is a matter of monitoring the grip of the steering wheel rim, or the driver/front passenger recognition, which, for example, involves activating or deactivating specific comfort functions in a manner specific to seat position. It is therefore advisable to use the heating wire in a non-heating phase in so-called measuring operation as an electrode for capacitive approach detection. Since the heating operation is usually performed with a pulse-width-modulated heating current, there are phases in which no heating current is present, which are used for measuring operation. In order to prevent interference in the measuring capacitances formed between the heating wire as capacitive electrode and a reference electrode or the ground potential during measuring operation “on all sides”, that is to say from all poles of the heating voltage that provide the heating current, it is known from DE 11 2014 002 044 T5, for example, to provide all-pole disconnection of the heating wire from those poles that provide different heating potentials by means of field-effect transistors during measuring operation. Switching devices, in particular field-effect transistors, have parasitic capacitances, which can interfere with the determination of the actual measuring capacitance. US 2010/0038351 A1 proposes to support the insulating effect of the blocking switching devices in measuring operation through additional impedances, in particular diodes, wherein a shielding signal can additionally be applied to the connecting line between the diodes and the switching devices. Such a solution has the disadvantage that the additional impedances, in particular the diodes, influence the heating current, in particular have ohmic losses, and thus the electrical heating voltage cannot be optimally converted into thermal heating power which is output by the heating wire (Joule heat). Another problem with using the heating wire as an electrode for capacitive approach detection is that the electrode is subject to a high thermal load and thermally induced expansion fluctuations due to the change between heating operation and measuring operation as non-heating operation, which ultimately also results in a failure of the heating wire but also fluctuations in the sensitivity of the detection circuit connected to the heating wire.

Against this background, it is the object of the present disclosure to provide a circuit configuration for alternating heating and capacitive measuring operation, in which, in addition to the efficient use of the heating current in heating operation, the reliability of the capacitive approach measurement in measuring operation is at least ensured or even improved at the same time.

This object is achieved by the circuit configuration of claim 1. Further features, embodiments, properties and advantages result from the dependent claims, the description and the figures. A method according to the present disclosure for carrying out alternating heating and capacitive measuring operation by means of a common heating wire and the inventive use of the circuit configuration are the subject matter of the coordinate claims.

### SUMMARY

The present disclosure relates to an electrical circuit configuration for alternating heating and capacitive measuring operation using a common heating wire, wherein, in heating operation, the heating wire, for example a resistance wire, such as a nickel-chromium wire, has electric heating current, which is fed from two poles at two different heating potentials, passed through it, wherein a heating voltage drops across the heating wire. The circuit configuration includes a pair of first switching elements and a pair of second switching elements. The first switching elements are preferably formed by a transistor, preferably in each case by a field-effect transistor, usually preferably a metal-oxide-semiconductor field-effect transistor (MOSFET). The first and second switching elements are even more preferably realized by a transistor, preferably in each case by a field-effect transistor, usually preferably a metal-oxide-semiconductor field-effect transistor (MOSFET). The heating wire is connected to the first and second switching elements in such a way that, in heating operation, during which the first and second switching elements, thus simultaneously, are in the conducting state, the first and second switching elements and the heating wire are connected in series.

In this case, the heating wire is conductively connected to one of two different heating potentials via a first switching element and a second switching element connected to the first switching element via a conductor section, for example vehicle ground on one side and the positive battery potential on the other side. As a result of the fact that the first and second switching elements are turned on in heating operation, the heating wire has the heating current passing through it. If at least one switching element of the first and second switching elements is in the non-conducting or blocking state, there is no heating current present. Periodically switching over and changing the duration of the respective heating operation, for example by actuating at least one or all switching elements by means of a pulse-width-modulated signal, can thus adjust the heating power of the heating wire.

According to the present disclosure, a detection circuit is also provided in order to determine the measuring capacitance of the heating wire with respect to a reference potential, for example that of a reference electrode or the vehicle ground, by applying an AC voltage to the heating wire from an AC voltage source in a measuring operation falling outside of the time frame of the heating operation. Based on a change in this measuring capacitance, for example, an approach of a vehicle occupant or at least the approach of a hand of the vehicle occupant can be detected. Different methods are known for determining the measuring capacitance of this type. According to the present disclosure, such methods in which the measuring capacitance can be reliably detected by applying an AC voltage to the heating wire as a transmitting electrode are used here. Amplitude-modulated detection circuits supply high-frequency alternating current (for example 20 kHz) to the capacitor which is to be measured and is formed by the heating wire and detect the resulting reactive current.

In frequency-modulated detection circuits, the measuring capacitance which is to be measured is interconnected with an inductance to form a resonant circuit as part of an LC oscillator whose frequency is measured by comparing it to a reference. In another variant of the frequency-modulated detection circuit, the measuring capacitance is part of an unstable multivibrator. The detection circuit is preferably designed to measure a current profile between the heating wire and the AC voltage source resulting from the application of the AC voltage in measuring operation, in order to determine therefrom the respective measuring capacitance based on a phase shift between the AC voltage and the current profile. For example, the current profile is measured based on a voltage drop across a shunt resistor with signal amplification by way of a measuring amplifier.

According to the present disclosure, a control circuit is also provided in order to switch the first switching elements and second switching elements from heating operation to measuring operation, during which the first switching elements and the second switching elements are in a blocking state, such that the two connections of the heating wire that are electrically conducting in heating operation at the two different heating potentials are each interrupted multiple times in measuring operation. The multiple interruptions to the two heating potentials has the advantage that, in addition to the particularly effective, capacitive decoupling of the heating wire with respect to the heating potentials and the reduction in the parasitic capacitances on the connection to the heating potentials that is interrupted multiple times, in which the switching elements are now to be regarded as capacitive impedances which are connected in series, furthermore a detection circuit that uses an AC voltage can be used in an improved manner since the first switching elements, for example different to the asymmetrically switched diodes in the prior art, isolate symmetrically and this isolation affects both current directions of the alternating current generated in measuring operation, which facilitates and improves the determination of the measuring capacitance by means of AC voltage, but especially the preferred way of detecting the phase shift.

According to the present disclosure, the control circuit is further designed to switch a test circuit containing at least one third switching element and a test impedance in a test phase falling within the measuring operation in such a way that the test impedance is added to the measuring capacitance, and an associated change in measuring capacitance and/or a total impedance made up of the measuring capacitance and the test impedance is at least detected by the detection circuit. For example, a change in the measuring capacitance caused by the connection of the test impedance is detected only qualitatively. In another embodiment, a quantitative measurement of the resulting total impedance made up of measuring capacitance and test impedance is provided to enable a calibration of the detection circuit by means of the predetermined test impedance. In a simple configuration, only the temporal coincidence between the change in measuring capacitance and the change in the switching state is investigated. Providing the test phase and the associated design features makes it possible, through comparatively simple technical constructive expansion of a heating and measuring circuit, on the one hand to check the integrity of the heating wire but also the function of the detection circuit and, in quantitative investigation, for example by determining the change in measuring capacitance or the total impedance resulting in the test phase, to calibrate the detection circuit or downstream evaluation devices. The duration of the test phase is preferably shorter than the duration of a measuring operation carried out between two subsequent heating operations. In the time range falling outside the test phase, at least one third switching element is in a blocking state. For example, the time ratio of the duration of the test phase to the total duration of the measuring operation containing the test phase is less than 1/10.

In one embodiment, the test phase takes place exclusively over a period within which an approach of a hand to the steering wheel is excluded, for example in the locked, unoccupied state of the vehicle cabin. In another embodiment, the test phase is carried out only if no approach was detected in a temporally preceding measuring operation falling outside the test phase. In one configuration, the test phase is carried out at the beginning of a measuring operation. In the alternating sequence of heating and measuring operation, provision may be made, in the case of several measuring operations, for at least one to be carried out without a test phase, preferably for the majority of measuring operations to be carried out without a test phase.

For example, connection involves connecting a test impedance in series with the measuring capacitance. However, provision is preferably made for the test impedance belonging to the test circuit to be connected in parallel with the measuring capacitance in the test phase.

In the test phase, at least one third switching element preferably electrically conductively connects the heating wire to the reference potential via the test impedance. The test impedance may be formed by an ohmic resistor only; the test impedance is preferably formed by a capacitor with a predetermined test capacitance. Even more preferably, the test impedance is formed by the parallel connection of a capacitor with a predetermined test capacitance and an ohmic resistor. Provision is preferably made for the test impedance to be varied by changing one or more switching states of the third switching elements during the test phase.

In order to reduce parasitic capacitances, the third switching element is preferably a bipolar transistor in each case.

The circuit configuration is preferably designed so that the heating operation and measuring operation are operated in alternation. For example, the control circuit is designed to generate a pulse-width-modulated control signal for the first and/or second switching elements. Furthermore, a microcontroller is provided, for example, to vary the duty cycle of the pulse-width-modulated control signal as a function of a desired and/or predetermined heating power.

According to a preferred embodiment of the circuit configuration according to the present disclosure, a shielding circuit is also provided, which is designed to apply the AC voltage of the AC voltage source to at least one of the conductor sections between each of the first and second switching element during the measuring operation. In this case, the renewed use of the term AC voltage is intended to ensure that the AC voltage applied to the heating wire in measuring operation and the AC voltage applied to the conductor sections essentially correspond in terms of amplitude, frequency and phase in order to achieve optimum shielding.

It has been shown that parasitic effects of the third switching elements during measuring operation are better to avoid if, according to a preferred embodiment, a first terminal of at least one of the components forming the test impedance, for example the capacitor, is permanently electrically connected to the heating wire and the third switching element is provided to apply the reference potential selectively to a second terminal of the respective component forming the test impedance exclusively in the test phase. However, in order to avoid the parasitic effects of at least one of the components of the test impedance which cannot be electrically isolated from the heating wire, the shielding circuit is designed to apply the AC voltage of the AC voltage source to the second terminal of at least one of the components forming the test impedance at least during the measuring operation, preferably permanently.

According to a preferred embodiment, a fourth switching element is provided, which electrically isolates the second terminal from the reference potential exclusively in measuring operation, as a result of which the electrical load distribution between measuring operation and test phase relating to the shielding circuit is balanced.

According to a preferred embodiment, at least the first switching elements are transistors, in particular field-effect transistors. In this case, the shielding circuit is also designed such that, in measuring operation, the AC voltage is applied in each case to a control terminal of the associated transistor, such as base or gate, in order to achieve particularly effective shielding. In this case, the AC voltage and/or the first switching elements are designed in such a way that a switching process of the first switching elements in measuring operation is excluded.

In a preferred embodiment, the detection circuit is supplemented by a compensation circuit in order to compensate for a temperature-dependent blocking behavior of the first switching elements, in particular if said first switching elements are designed as field-effect transistors and cannot fully suppress a temperature-dependent reactive current. To compensate for this, the compensation circuit is designed, for example, to change the operating point of the measuring amplifier measuring the alternating current profile in a manner dependent on temperature so as to counteract the change in the blocking behavior. For this purpose, the compensation circuit includes, for example, a microcontroller-controlled reference circuit which forms an R2R network.

The present disclosure further relates to the use of the circuit configuration in one of the embodiments described above in a motor vehicle, wherein the heating wire is integrated in a steering wheel of the motor vehicle, for example in a steering wheel rim of the steering wheel.

The present disclosure further relates to a method for carrying out an alternating heating and capacitive measuring operation by means of a common heating wire, comprising the following steps.

In a heating operation, a pair of first switching elements and a pair of second switching elements are switched to a conducting state by means of a control circuit. During this heating operation, the first switching elements and the second switching elements and the heating wire are connected in series. Furthermore, in heating operation, the heating wire is conductively connected to one of two different heating potentials via a first switching element and a second switching element connected to the first switching element via a conductor section, such that a heating current is applied to the heating wire on account of the different heating potentials.

In a subsequent step, a change from heating operation to measuring operation of the first switching elements and the second switching elements is initiated by way of the control circuit, wherein, during measuring operation, the first switching elements and the second switching elements are in a blocking state. As a result thereof, the two connections of the heating wire that are electrically conductive in heating operation at the two different heating potentials are each interrupted several times in measuring operation. During the measuring operation, the measuring capacitance of the heating wire is determined with respect to a reference potential by applying an AC voltage to the heating wire by way of a detection circuit. Subsequently, there is preferably a change from measuring operation to heating operation, even more preferably heating operation and measuring operation are operated in alternation.

According to the present disclosure, a test phase is carried out within the time frame of the measuring operation, during which, by means of a test circuit containing at least one third switching element and a test impedance, the test circuit is switched by way of the control circuit in such a way that a test impedance is added to the measuring capacitance and an associated change in measuring capacitance and/or a total impedance made up of the measuring capacitance and the test impedance is at least detected by the detection circuit.

For example, a change in the measuring capacitance caused by the connection of the test impedance is detected only qualitatively. In another embodiment, a quantitative measurement of the resulting total impedance made up of measuring capacitance and test impedance is provided to enable a calibration of the detection circuit by means of the predetermined test impedance. In a simple configuration, only the temporal coincidence between the change in measuring capacitance and the change in the switching state is investigated.

Providing the test phase and the associated design features makes it possible, through comparatively simple technical constructive expansion of a heating and measuring circuit, on the one hand to check the integrity of the heating wire but also the function of the detection circuit and, in quantitative investigation, for example by determining the change in measuring capacitance or the total impedance resulting in the test phase, to calibrate the detection circuit or downstream evaluation devices. The duration of the test phase is preferably shorter than the duration of a measuring operation carried out between two subsequent heating operations. In the time range falling outside the test phase, at least one third switching element is in a blocking state. For example, the time ratio of the duration of the test phase to the total duration of the measuring operation containing the test phase is less than 1/10.

In one embodiment, the test phase takes place exclusively over a period within which an approach of a hand to the steering wheel is excluded, for example in the locked, unoccupied state of the vehicle cabin. In another embodiment, the test phase is carried out only if no approach was detected in a temporally preceding measuring operation falling outside the test phase. In one configuration, the test phase is carried out at the beginning of a measuring operation. In the alternating sequence of heating and measuring operation, provision may be made, in the case of several measuring operations, for at least one to be carried out without a test phase, preferably for the majority of measuring operations to be carried out without a test phase.

For example, connection involves connecting a test impedance in series with the measuring capacitance. However, provision is preferably made for the test impedance belonging to the test circuit to be connected in parallel with the measuring capacitance during the test phase.

In the test phase, at least one third switching element preferably electrically conductively connects the heating wire to the reference potential via the test impedance. The test impedance is preferably formed by a capacitor with a predetermined test capacitance. Even more preferably, the test impedance is formed by the parallel connection of a capacitor with a predetermined test capacitance and an ohmic resistor. Provision is preferably made for the test impedance to be varied by changing one or more switching states of the third switching elements during the test phase.

In order to prevent parasitic capacitances, the third switching element is preferably a bipolar transistor in each case.

According to a preferred embodiment of the circuit configuration according to the present disclosure, a shielding circuit is also provided, which is designed to apply the AC voltage of the AC voltage source to at least one of the conductor sections between each of the first and second switching element during the measuring operation. In this case, the renewed use of the term AC voltage is intended to ensure that the AC voltage applied to the heating wire in measuring operation and the AC voltage applied to the conductor sections essentially correspond in terms of amplitude, frequency and phase in order to achieve optimum shielding.

It has been shown that parasitic effects of the third switching elements during measuring operation are better to avoid if, according to a preferred embodiment, a first terminal of at least one of the components forming the test impedance, for example the capacitor, is permanently electrically connected to the heating wire and the third switching element is provided to apply the reference potential selectively to a second terminal of the respective component forming the test impedance exclusively in the test phase. However, in order to avoid the parasitic effects of at least one component of the test impedance which cannot be electrically isolated from the heating wire, the shielding circuit is designed to apply the AC voltage of the AC voltage source to the second terminal of at least one of the components forming the test impedance at least during the measuring operation, preferably permanently.

According to a preferred embodiment, a fourth switching element is provided, which electrically isolates the second terminal from the reference potential exclusively in measuring operation, as a result of which the electrical load distribution between measuring operation and test phase relating to the shielding circuit is balanced.

According to a preferred embodiment, at least the first switching elements are realized by transistors, in particular field-effect transistors, wherein, through design of the shielding circuit, the AC voltage in measuring operation is applied to a control terminal of the associated transistor, such as base or gate, in order to achieve particularly effective shielding. In this case, the AC voltage and/or the first switching elements are designed in such a way that a switching process of the first switching elements in measuring operation is excluded.

According to a preferred embodiment of the method, a current profile between the heating wire and the AC voltage source resulting from the application of the AC voltage is measured in measuring operation by way of the detection circuit, in order to determine therefrom the capacitance based on a phase shift between the AC voltage and the current profile.

According to a preferred embodiment of the method, a temperature-dependent blocking behavior of the first switching elements is compensated for during detection, in particular if said first switching elements are designed as field-effect transistors and cannot fully suppress a temperature-dependent reactive current. To compensate for this, the detection circuit is supplemented by a compensation circuit which changes the operating point of the measuring amplifier measuring the alternating current profile in a manner dependent on temperature and counteracting the change in the blocking behavior. For this purpose, the compensation circuit includes, for example, a microcontroller-controlled reference circuit which forms an R2R network.

### BRIEF DESCRIPTION OF THE DRAWINGS

The present disclosure is explained in more detail using the following figures. The figures are to be understood here purely as examples and represent only a preferred embodiment. In the figures:

FIG. 1 shows a schematic view of a steering wheel with a heating wire integrated therein, belonging to the circuit configuration according to an embodiment;

FIG. 2 shows a schematic view of the circuit configuration according to a first embodiment;

FIG. 3 shows a schematic view of the circuit configuration according to a second embodiment.

### DETAILED DESCRIPTION

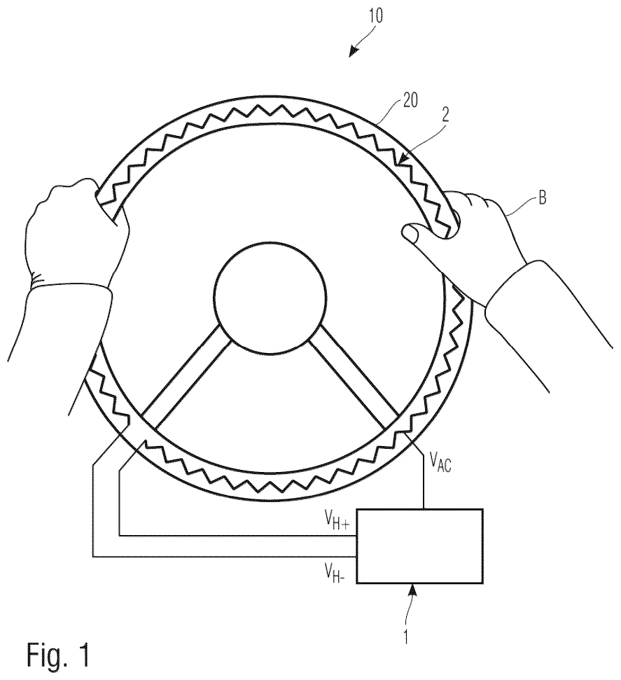

FIG. 1 shows the use of the circuit configuration 1 according to an embodiment in a steering wheel 10 of a motor vehicle, which is not shown. A heating wire 2, which is, for example, a resistance wire, such as a nickel-chrome wire, is integrated in the grip area 20, here the steering wheel rim, of the steering wheel, on the one hand to heat the grip area 20 for a vehicle occupant B gripping the steering wheel 10 in a heating operation of the circuit configuration 1 and on the other hand to carry out capacitive touch detection or approach detection regarding the hand of the vehicle occupant B touching the grip area 20 or approaching the grip area 20. For safety considerations, but also to realize additional comfort functions, said touch detection or at least approach detection is provided in order to carry out so-called hands-on detection, for example, in which it is a matter of monitoring the grip of the steering wheel rim, or to carry out driver/front passenger recognition, which, for example, involves activating or deactivating specific comfort functions in a manner specific to seat position. As FIG. 1 indicates, in heating operation, a heating current from the different heating potentials V_{H+}, V_{H-} is applied to the heating wire 2. For example, V_{H-} is at vehicle ground potential. In measuring operation, an AC voltage V_{AC} is applied to the heating wire 2 by the inventive circuit configuration 1.

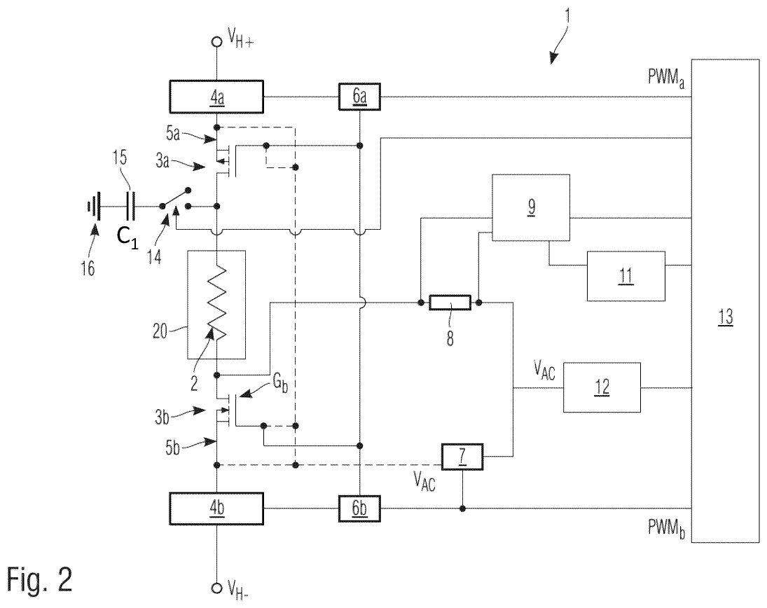

FIG. 2 schematically shows the electrical circuit configuration 1 for alternating heating and capacitive measuring operation using a common heating wire 2 in a first embodiment. In this case, in heating operation, an electric heating current fed from two poles at the two different heating potentials V_{H+}, V_{H-} passes through the heating wire 2, whereby a heating voltage drops across the heating wire 2. The circuit configuration 1 includes to this end a pair of first switching elements 3a, 3b and a pair of second switching elements 4a, 4b. Here, the first switching elements 3a, 3b are in each case formed by a field-effect transistor, in particular a normally off field-effect transistor, preferably a metal-oxide-semiconductor field-effect transistor (MOSFET). For example, the second switching elements 4a, 4b are also each realized by a transistor, preferably in each case by a field-effect transistor, usually preferably a metal-oxide-semiconductor field-effect transistor (MOSFET). The heating wire 2 is connected to the first switching elements 3a, 3b and the second switching elements 4a, 4b in such a way that, in heating operation, during which the first switching elements 3a, 3b and the second switching elements 4a, 4b, thus simultaneously, are in the conducting state, the first switching elements 3a, 3b and the second switching elements 4a, 4b and the heating wire 2 are connected in series. In this case, the heating wire 2 is conductively connected to one of two different heating potentials V_{H+}, V_{H-} via a first switching element 3a, 3b and a second switching element 4a, 4b connected to the first switching element 3a, 3b via a conductor section 5a, 5b. As a result of the fact that the first switching elements 3a, 3b and the second switching elements 4a, 4b are turned on (conducting) in heating operation, the heating wire 2 has the heating current passing through it. If at least one switching element of the first switching elements 3a, 3b and second switching elements 4a, 4b is in the non-conducting or blocking state, there is no heating current present. Periodically switching over and changing the duration of the respective heating operation, for example by actuating at least one or all switching elements 3a, 3b; 4a, 4b by means of a pulse-width-modulated signal PWMₐ and PWM_{b}, respectively, of a microcontroller 13 which is part of the control circuit 6a, 6b, 13 and which actuates the control circuit part 6a, 6b of the control circuit 6a, 6b, 13 that is assigned to the switching elements 3a, 3b; 4a, 4b, can thus adjust the heating power of the heating wire 2. During the heating operation, the third switching element 14 belonging to the test circuit 14, 15, described in detail below, is switched to the blocking state.

According to an embodiment, a detection circuit 9 is also provided in order to determine the measuring capacitance of the heating wire 2 with respect to a reference potential 16, such as the vehicle ground, by applying an AC voltage V_{AC} to the heating wire 2 from an AC voltage source 12, in this case a sinus generator controlled by the microcontroller 13, in a measuring operation falling outside of the time frame of the heating operation. Based on a change in this capacitance, for example, a proximity of a vehicle occupant B or at least the proximity of a hand of the vehicle occupant B can be detected. In this case, the detection circuit 9 is designed to measure a current profile between the heating wire 2 and the AC voltage source 12 resulting from the application of the AC voltage V_{AC} in measuring operation, in order to determine therefrom the capacitance based on a phase shift between the AC voltage V_{AC} and the current profile. In detail, the current profile is measured based on a voltage drop across a shunt resistor 8 with signal amplification by way of a measuring amplifier of the detection circuit, the measurement result of which is transmitted to the microcontroller 13.

The change from heating operation to measuring operation is initiated by way of the microcontroller 13 in cooperation with the control circuit parts 6a, 6b, such that, in measuring operation, the first switching elements 3a, 3b and the second switching elements 4a, 4b are in a blocking state, such that the two connections of the heating wire 2 that are electrically conductive in heating operation at the two different heating potentials V_{H+}, V_{H-} are each interrupted several times in measuring operation.

The multiple interruptions to the two heating potentials V_{H+}, V_{H-} has the advantage that, in addition to the particularly effective, capacitive decoupling of the heating wire 2 with respect to the heating potentials V_{H+}, V_{H-} and the reduction in the parasitic capacitances on the connection to the heating potentials V_{H+}, V_{H-} that is interrupted multiple times, in which the switching elements 3a, 3b; 4a, 4b are now to be regarded as capacitive impedances which are connected in series, furthermore a detection circuit 9 that uses an AC voltage V_{AC} can be used in an improved manner since the first switching elements 3a, 3b, for example different to the asymmetrically switched diodes in the prior art, isolate symmetrically and this isolation affects both current directions of the alternating current generated in measuring operation, which facilitates and improves the determination of the measuring capacitance by means of AC voltage V_{AC}, but especially the preferred way of detecting the phase shift. By the actuation by means of the pulse-width-modulated control signals PWMₐ and PWM_{b}, respectively, of the control circuit parts 6a, 6b by way of the microcontroller 13, the circuit configuration 1 is designed such that the heating operation and measuring operation is operated in alternation. The microcontroller 13 in this case regulates the duty cycle of the pulse-width-modulated control signals PWMₐ and PWM_{b}, respectively, depending on a desired and/or predetermined heating power.

In the circuit configuration 1 according to an embodiment shown, a shielding circuit 7 is also provided, which is designed, during the measuring operation, to apply the AC voltage V_{AC} of the AC voltage source 12 not only to the conductor section 5a, 5b between each of the first switching element 3a, 3b and the second switching element 4a, 4b, but also the control terminals Ga, Gb of the first switching elements 3a, 3b. In this case, the use of the term AC voltage is intended to ensure that the AC voltage applied to the heating wire 2 in measuring operation and the AC voltage V_{AC} applied to the conductor sections 5a, 5b essentially correspond in terms of amplitude, frequency and phase in order to achieve optimum shielding.

The detection circuit 9 is supplemented by a compensation circuit 11 in order to compensate for a temperature-dependent blocking behavior of the first switching elements 3a, 3b in order to compensate for a temperature-dependent reactive current or a temperature-dependent blocking behavior of said first switching elements 3a, 3b. Here, the compensation circuit 11 is provided and designed to change the operating point of the measuring amplifier of the detection circuit 9 measuring the alternating current profile in a manner dependent on temperature so as to counteract the change in the blocking behavior. For this purpose, the compensation circuit includes, for example, a reference circuit which forms an R2R network, said reference circuit being connected to the microcontroller 13 for the purpose of controlling the compensation.

According to an embodiment, the control circuit 6a, 6b, 13 is further designed to switch a test circuit 14, 15 containing a third switching element 14 and a test impedance 15 in a test phase falling within the measuring operation in such a way that the test impedance 15 is added to the measuring capacitance, and an associated change in measuring capacitance and/or a total impedance made up of the measuring capacitance and the test impedance is at least detected by the detection circuit 9. For example, a change in the measuring capacitance caused by the connection of the test impedance 15 is detected only qualitatively. In another embodiment, a quantitative measurement of the resulting total impedance made up of measuring capacitance and test impedance 15 is provided to enable a calibration of the detection circuit by means of the predetermined test impedance. In a simple configuration, only the temporal coincidence between the change in measuring capacitance and the change in the switching state is investigated. Providing the test phase and the associated design features makes it possible, through comparatively simple technical constructive expansion of a heating and measuring circuit, on the one hand to check the integrity of the heating wire 2 but also the function of the detection circuit 9 and, in quantitative investigation, for example by determining the change in measuring capacitance or the total impedance resulting in the test phase, to calibrate the detection circuit 9 or downstream evaluation devices. The duration of the test phase is preferably shorter than the duration of a measuring operation carried out between two subsequent heating operations. In the time range of the measuring operation falling outside the test phase, at least the third switching element 14 is in a blocking state. In order to be able to check the heating wire 2 over its entire length, the AC voltage V_{AC} is fed in at one end of the heating wire 2, while the test impedance 15 is connected at the opposite end of the heating wire 2, so that the test impedance 15 belonging to the test circuit 14, 15 is connected in parallel with the measuring capacitance in the test phase. In this case, in the test phase, the third switching element 14 electrically conductively connects the heating wire 2 to the reference potential 16 via the test impedance 15. The test impedance 15 is a capacitor with a predetermined test capacitance. In order to prevent parasitic capacitances, the third switching element 14 is a bipolar transistor. For example, the time ratio of the duration of the test phase to the total duration of the measuring operation containing the test phase is less than 1/10.

The chronological sequence of heating operation and measuring operation is not illustrated in any more detail. In one embodiment, the test phase takes place exclusively over a period within which an approach of a hand to the steering wheel is excluded, for example in the locked, unoccupied state of the vehicle cabin. In another embodiment, the test phase is carried out only if no approach was detected in a temporally preceding measuring operation falling outside the test phase. In one configuration, the test phase is carried out at the beginning of a measuring operation. In the alternating sequence of heating and measuring operation, provision may be made, in the case of several measuring operations, for at least one to be carried out without a test phase, preferably for the majority of measuring operations to be carried out without a test phase.

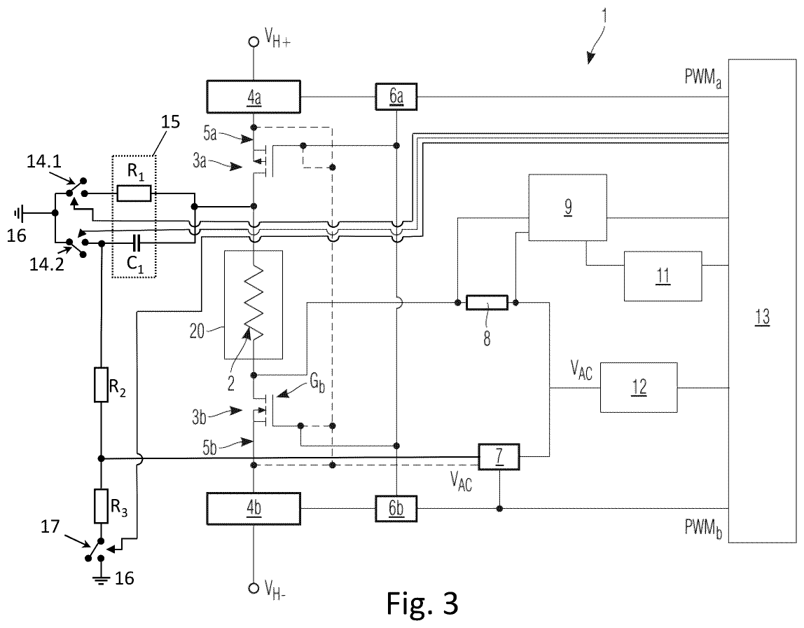

FIG. 3 schematically shows the electrical circuit configuration 1 for alternating heating and capacitive measuring operation using a common heating wire 2 in a second embodiment. In this case, as in the first embodiment, in heating operation, an electric heating current fed from two poles at the two different heating potentials V_{H+}, V_{H-} passes through the heating wire 2, whereby a heating voltage drops across the heating wire 2. The circuit configuration 1 includes to this end a pair of first switching elements 3a, 3b and a pair of second switching elements 4a, 4b. Here, too, the first switching elements 3a, 3b are in each case formed by a field-effect transistor, in particular a normally off field-effect transistor, preferably a metal-oxide-semiconductor field-effect transistor (MOSFET). For example, the second switching elements 4a, 4b are also each realized by a transistor, preferably in each case by a field-effect transistor, usually preferably a metal-oxide-semiconductor field-effect transistor (MOSFET). The heating wire 2 is connected to the first switching elements 3a, 3b and the second switching elements 4a, 4b in such a way that, in heating operation, during which the first switching elements 3a, 3b and the second switching elements 4a, 4b, thus simultaneously, are in the conducting state, the first switching elements 3a, 3b and the second switching elements 4a, 4b and the heating wire 2 are connected in series. In this case, the heating wire 2 is conductively connected to one of two different heating potentials V_{H+}, V_{H-} via a first switching element 3a, 3b and a second switching element 4a, 4b connected to the first switching element 3a, 3b via a conductor section 5a, 5b. As a result of the fact that the first switching elements 3a, 3b and the second switching elements 4a, 4b are turned on (conducting) in heating operation, the heating wire 2 has the heating current passing through it. If at least one switching element of the first switching elements 3a, 3b and second switching elements 4a, 4b is in the non-conducting or blocking state, there is no heating current present. Periodically switching over and changing the duration of the respective heating operation, for example by actuating at least one or all switching elements 3a, 3b; 4a, 4b by means of a pulse-width-modulated signal PWMₐ and PWM_{b}, respectively, of a microcontroller 13 which is part of the control circuit 6a, 6b, 13 and which actuates the control circuit part 6a, 6b of the control circuit 6a, 6b, 13 that is assigned to the switching elements 3a, 3b; 4a, 4b, can thus adjust the heating power of the heating wire 2. During the heating operation, the third switching element 14.1, 14.2 belonging to the test circuit 14.1, 14.2; 15, explained in detail below, is switched to the blocking state.

According to an embodiment, a detection circuit 9 is also provided in order to determine the measuring capacitance of the heating wire 2 with respect to a reference potential 16, such as the vehicle ground, by applying an AC voltage V_{AC} to the heating wire 2 from an AC voltage source 12, in this case a sinus generator controlled by the microcontroller 13, in a measuring operation falling outside of the time frame of the heating operation. Based on a change in this capacitance, for example, a proximity of a vehicle occupant B or at least the proximity of a hand of the vehicle occupant B can be detected. In this case, the detection circuit 9 is designed to measure a current profile between the heating wire 2 and the AC voltage source 12 resulting from the application of the AC voltage V_{AC} in measuring operation, in order to determine therefrom the capacitance based on a phase shift between the AC voltage V_{AC} and the current profile. In detail, the current profile is measured based on a voltage drop across a shunt resistor 8 with signal amplification by way of a measuring amplifier of the detection circuit 9, the measurement result of which is transmitted to the microcontroller 13.

The change from heating operation to measuring operation is initiated by way of the microcontroller 13 in cooperation with the control circuit parts 6a, 6b, such that, in measuring operation, the first switching elements 3a, 3b and the second switching elements 4a, 4b are in a blocking state, such that the two connections of the heating wire 2 that are electrically conductive in heating operation at the two different heating potentials V_{H+}, V_{H-} are each interrupted several times in measuring operation.

The multiple interruptions to the two heating potentials V_{H+}, V_{H-} has the advantage that, in addition to the particularly effective, capacitive decoupling of the heating wire 2 with respect to the heating potentials V_{H+}, V_{H-} and the reduction in the parasitic capacitances on the connection to the heating potentials V_{H+}, V_{H-} that is interrupted multiple times, in which the switching elements 3a, 3b; 4a, 4b are now to be regarded as capacitive impedances which are connected in series, furthermore a detection circuit 9 that uses an AC voltage V_{AC} can be used in an improved manner since the first switching elements 3a, 3b, for example different to the asymmetrically switched diodes in the prior art, isolate symmetrically and this isolation affects both current directions of the alternating current generated in measuring operation, which facilitates and improves the determination of the measuring capacitance by means of AC voltage V_{AC}, but especially the preferred way of detecting the phase shift. By the actuation by means of the pulse-width-modulated control signals PWMₐ and PWM_{b}, respectively, of the control circuit parts 6a, 6b by way of the microcontroller 13, the circuit configuration 1 is designed such that the heating operation and measuring operation are operated in alternation. The microcontroller 13 in this case regulates the duty cycle of the pulse-width-modulated control signals PWMₐ and PWM_{b}, respectively, depending on a desired and/or predetermined heating power.

In the circuit configuration 1 according to an embodiment shown, a shielding circuit 7 is also provided, which is designed, during the measuring operation, to apply the AC voltage V_{AC} of the AC voltage source 12 not only to the conductor section 5a, 5b between each of the first switching element 3a, 3b and the second switching element 4a, 4b, but also the control terminals Ga, Gb of the first switching elements 3a, 3b. In this case, the use of the term AC voltage is intended to ensure that the AC voltage applied to the heating wire 2 in measuring operation and the AC voltage V_{AC} applied to the conductor sections 5a, 5b essentially correspond in terms of amplitude, frequency and phase in order to achieve optimum shielding. In certain areas of application, provision may be made for the AC voltage V_{AC} of the AC voltage source 12 to be applied to only one of the conductor sections 5a, 5b and only one of the control terminals Ga, Gb.

In contrast to FIG. 2, in the embodiment according to FIG. 3, the third switching element 14.1, 14.2 is not interconnected between the heating wire 2 and the component forming the test impedance, for example the capacitor C₁, but instead is interconnected between the respective component and the reference potential 16. It has been shown specifically that parasitic effects of the third switching elements in the interconnection according to FIG. 2 cannot be avoided.

In the embodiment shown in FIG. 3, a first terminal of both of the components forming the test impedance, the ohmic resistor R₁ and the capacitor C₁, is permanently electrically connected to the heating wire 2. The respective third switching element 14.1 or 14.2 is provided to selectively apply the reference potential 16 to a second terminal of the respective component C₁ and R₁, respectively, forming the test impedance in the test phase only. However, in order to avoid the parasitic effects of at least one component of the test impedance, in this case C₁, which cannot be electrically isolated from the heating wire 2, the shielding circuit 7 is designed in the embodiment shown to apply the AC voltage V_{AC} of the AC voltage source 12 via the resistor R₂ to the second terminal at least in measuring operation, preferably permanently. As a result, the capacitor C₁ is “neutralized” and does not have a parasitic effect. To function as a capacitive test impedance 15 on the heating wire 2, the capacitor C₁ is “activated” when the switch 14.2 is closed. Since this process represents a change in load on the active shielding circuit 7, which should absolutely be avoided, the resistor R₃ is provided as load compensation added in a current path which can be switched selectively by means of a fourth switching element 17, wherein the resistance value is R₃=R₂. This is deactivated as load compensation by means of an open fourth switch 17 only during the test phase. The switching states of the third switches 14.1, 14.2 which can be set by the microcontroller 13 thus determine the electrical properties of the test impedance 15 in the test phase. In the case of a closed third switch 14.1, an ohmic test impedance 15 determined primarily by the resistor R₁ is present, while in the case of a closed switch 14.2, a capacitive test impedance determined primarily by the capacitor C₁ is present. The switching states of the third switches 14.1 and 14.2 determine the test impedance in the real and imaginary part and influence the phase shift between current and voltage in the test phase. By evaluating the phase shift, the functionality of the signal source and detection circuit 9 can be inferred and, secondly, the integrity of the heating wire 2 can be inferred.

Providing the test phase and the associated design features makes it possible, through comparatively simple technical constructive expansion of a heating and measuring circuit, on the one hand to check the integrity of the heating wire 2 but also the function of the detection circuit 9 and by determining the change in measuring capacitance or the total impedance resulting in the test phase, to calibrate the detection circuit 9 or downstream evaluation devices. The duration of the test phase is preferably shorter than the duration of a measuring operation carried out between two subsequent heating operations. In the time range of the measuring operation falling outside the test phase, at least one of the third switching elements 14.1, 14.2 is in a blocking state. In order to be able to check the heating wire 2 over its entire length, the AC voltage V_{AC} is fed in at one end of the heating wire 2, while the test impedance 15 is connected at the opposite end of the heating wire 2, so that the test impedance 15 belonging to the test circuit 14, 15 is connected in parallel with the measuring capacitance in the test phase. In this case, in the test phase, at least one of the third switching elements 14.1 14.2 electrically conductively connects the heating wire 2 to the reference potential 16 via at least one component of the components forming the test impedance 15. For example, the time ratio of the duration of the test phase to the total duration of the measuring operation containing the test phase is less than 1/10.

The chronological sequence of heating operation and measuring operation is not illustrated in any more detail. In one embodiment, the test phase takes place exclusively over a period within which an approach of a hand to the steering wheel is excluded, for example in the locked, unoccupied state of the vehicle cabin. In another embodiment, the test phase is carried out only if no approach was detected in a temporally preceding measuring operation falling outside the test phase. In one configuration, the test phase is carried out at the beginning of a measuring operation. In the alternating sequence of heating and measuring operation, provision may be made, in the case of several measuring operations, for at least one to be carried out without a test phase, preferably for the majority of measuring operations to be carried out without a test phase. The detection circuit 9 is also supplemented by a compensation circuit 11 in order to compensate for a temperature-dependent blocking behavior of the first switching elements 3a, 3b in order to compensate for a temperature-dependent reactive current or a temperature-dependent blocking behavior of said first switching elements 3a, 3b. Here, the compensation circuit 11 is provided and designed to change the operating point of the measuring amplifier of the detection circuit 9 measuring the alternating current profile in a manner dependent on temperature so as to counteract the change in the blocking behavior. For this purpose, the compensation circuit includes, for example, a reference circuit which forms an R2R network, said reference circuit being connected to the microcontroller 13 for the purpose of controlling the compensation.

What is claimed is:

1. An electrical circuit configuration for an alternating heating and a capacitive measuring operation, comprising:
a pair of first switching elements and a pair of second switching elements;
a heating wire, which is connected to the pair of first switching elements and the pair of second switching elements in such a way that, in a heating operation during which the pair of first switching elements and the pair of second switching elements are in a conducting state, the pair of first switching elements and the pair of second switching elements and the heating wire are connected in series, and the heating wire is conductively connected to one of two different heating potentials via one of the pair of first switching elements and one of the pair of second switching elements connected to the pair of first switching elements via a conductor section, such that a heating current is applied to the heating wire;
a detection circuit configured to determine a measuring capacitance of the heating wire with respect to a reference potential by applying an AC voltage of an AC voltage source to the heating wire in a measuring operation falling outside a time frame of the heating operation;
a test circuit including at least one third switching element and a test impedance;
a control circuit adapted to switch the pair of first switching elements and the pair of second switching elements from the heating operation to the measuring operation, wherein, during the measuring operation, the pair of first switching elements and the pair of second switching elements are in a blocking state, such that the two connections of the heating wire that are electrically conducting in the heating operation at the two different heating potentials are each interrupted multiple times in the measuring operation and the control circuit is further adapted to switch the test circuit in a test phase falling within the measuring operation in such a way that the test impedance is added to the measuring capacitance, and an associated change in the measuring capacitance and/or a total impedance made up of the measuring capacitance and the test impedance is at least detected by the detection circuit.

2. The electrical circuit configuration as claimed in claim 1, wherein the test impedance is connected in parallel with the measuring capacitance in the test phase.

3. The electrical circuit configuration as claimed in claim 1, wherein the at least one third switching element is adapted to electrically conductively connect the heating wire to the reference potential via the test impedance.

4. The electrical circuit configuration as claimed in claim 1, wherein the test impedance is formed by a capacitor with a predetermined test capacitance.

5. The electrical circuit configuration as claimed in claim 1, wherein the test impedance is formed by a parallel connection of a capacitor with a predetermined test capacitance and an ohmic resistor.

6. The electrical circuit configuration as claimed in claim 1, wherein the test impedance is varied by changing at least one switching state of the at least one third switching element during the test phase.

7. The electrical circuit configuration as claimed in claim 1, wherein the at least one third switching element is a bipolar transistor in each case.

8. The electrical circuit configuration as claimed in claim 1, further comprising a shielding circuit, which is designed to apply the AC voltage of the AC voltage source to at least one of the conductor sections during the measuring operation.

9. The electrical circuit configuration as claimed in claim 8, wherein a first terminal of at least one component forming the test impedance is permanently electrically connected to the heating wire and the at least one third switching element is adapted to apply the reference potential selectively to a second terminal of the respective component forming the test impedance exclusively in the test phase, wherein the component forming the test impedance is at least one of: a capacitor and a ohmic resistor.

10. The electrical circuit configuration as claimed claim 9, wherein the shielding circuit is designed to apply the AC voltage of the AC voltage source to the second terminal of the at least one component forming the test impedance.

11. The electrical circuit configuration as claimed in claim 10, further comprising a fourth switching element is adapted to electrically isolate the second terminal from the reference potential exclusively during the test phase.

12. The electrical circuit configuration as claimed in claim 8, wherein at least the pair of first switching elements are transistors, and the shielding circuit is configured such that, in the measuring operation, the AC voltage is applied in each case to a control terminal of an associated transistor, wherein the control terminal is any one of: a base and a gate.

13. The electrical circuit configuration as claimed in claim 1, wherein the detection circuit is adapted, in the measuring operation, to measure a current profile between the heating wire and the AC voltage source resulting from an application of the AC voltage in order to determine therefrom the measuring capacitance based on a phase shift between the AC voltage and the current profile and in the test phase to detect the change in the measuring capacitance and/or to determine the total impedance.

14. The electrical circuit configuration as claimed in claim 1, wherein the detection circuit is supplemented by a compensation circuit configured to compensate for a temperature-dependent blocking behavior of the pair of first switching elements.

15. The electrical circuit configuration as claimed in claim 1 is used in a motor vehicle, wherein the heating wire is integrated into a steering wheel of the motor vehicle.

16. A method for carrying out an alternating heating and capacitive measuring operation by a common heating wire, comprising the following steps:
carrying out a heating operation, during which a pair of first switching elements and a pair of second switching elements are in a conducting state owing to interconnection by way of a control circuit, the pair of first switching elements and the pair of second switching elements and the common heating wire are connected in series, and the common heating wire is conductively connected to one of two different heating potentials via one of the pair of first switching elements and one of the pair of second switching elements connected to the one of the pair of first switching elements via a conductor section, such that a heating current is applied to the common heating wire;
initiating a change from the heating operation to a measuring operation of the pair of first switching elements and the pair of second switching elements by way of the control circuit, wherein, during the measuring operation, the pair of first switching elements and the pair of second switching elements are in a blocking state, such that the two connections of the common heating wire that are electrically conductive in the heating operation at the two different heating potentials are each interrupted several times in the measuring operation;
carrying out the measuring operation in which a measuring capacitance of the common heating wire is determined with respect to a reference potential by applying an AC voltage of an AC voltage source to the common heating wire by way of a detection circuit;
carrying out a test phase falling within a time frame of the measuring operation, during which, by a test circuit containing at least one third switching element and a test impedance, the test circuit is switched by way of the control circuit in such a way that a test impedance is added to the measuring capacitance and an associated change in the measuring capacitance and/or a total impedance made up of the measuring capacitance and the test impedance is at least detected by the detection circuit.

17. The method as claimed in claim 16, wherein the test impedance is connected in parallel with the measuring capacitance in the test phase.

18. The method as claimed in claim 16, wherein, in the test phase, the common heating wire is electrically conductively connected to the reference potential via the test impedance by means of the at least one third switching element.

19. The method as claimed in claim 16, wherein the test impedance is formed by a capacitor with a predetermined test capacitance.

20. The method as claimed in claim 16, wherein the test impedance is formed by a parallel connection of a capacitor with a predetermined test capacitance and an ohmic resistor.

21. The method as claimed in claim 16, wherein the test impedance is varied by changing at least one switching state of the at least one third switching element during the test phase.

22. The method as claimed in claim 16, wherein the at least one third switching element is a bipolar transistor in each case.

23. The method as claimed in claim 16, wherein, during the measuring operation, a shielding circuit is used to apply the AC voltage of the AC voltage source to at least one of the conductor sections.

24. The method as claimed in claim 23, wherein a first terminal of at least one component forming the test impedance is permanently electrically connected to the common heating wire and the at least one third switching element is adapted to apply the reference potential selectively to a second terminal of the respective component forming the test impedance exclusively in the test phase, wherein the component forming the test impedance is at least one of: a capacitor and an ohmic resistor.

25. The method as claimed in claim 24, wherein the shielding circuit is designed to apply the AC voltage of the AC voltage source to the second terminal of the at least one component forming the test impedance.

26. The method as claimed in claim 25, wherein a fourth switching element is adapted to electrically isolate the second terminal from the reference potential exclusively during the test phase.

27. The method as claimed in claim 23, wherein at least the pair of first switching elements are transistors and the shielding circuit is used to apply the AC voltage in each case to a control terminal of an associated transistor, wherein the control terminal is any one of: a base and a gate.

28. The method as claimed in claim 16, wherein a current profile between the common heating wire and the AC voltage source resulting from an application of the AC voltage is measured in the measuring operation by way of the detection circuit, in order to detect the measuring capacitance based on a phase shift between the AC voltage and the current profile and in the test phase to detect the change in the measuring capacitance and/or to determine the total impedance.

29. The method as claimed in claim 16, wherein a temperature-dependent blocking behavior of the pair of first switching elements is compensated for in the measuring operation.

30. The electrical circuit configuration as claimed in claim 12, wherein the transistors are field-effect transistors.

31. The method as claimed in claim 27, wherein the transistors are field-effect transistors.
